(19) United States
(12) Patent Application Publication
(10) Pub. No.: US 2007/0279972 A1
(43) Pub. Date: Dec. 6, 2007

(54) MEMORY

(75) Inventors: Yutaka Higo, Miyagi (JP); Masanori Hosomi, Kanagawa (JP); Hiroyuki Ohmori, Kanagawa (JP); Tetsuya Yamamoto, Kanagawa (JP); Kazutaka Yamane, Miyagi (JP); Yuki Oishi, Kanagawa (JP); Hiroshi Kano, Kanagawa (JP)

Correspondence Address: BELL, BOYD & LLOYD, LLP, P. O. BOX 1135, CHICAGO, IL, 60690, US

(73) Assignee: SONY CORPORATION, Tokyo (JP)

(21) Appl. No.: 11/745,925

(22) Filed: May 8, 2007

(30) Foreign Application Priority Data
May 23, 2006 (JP) P2006-143100

(51) Int. Cl. G11C 11/00

(52) U.S. Cl. 365/158

(57) ABSTRACT

A memory including a memory element having a memory layer that retains information based on a magnetization state of a magnetic material, and a conductor electrically connected to the memory element is provided. In the memory, a magnetization pinned layer is provided for the memory layer through an intermediate layer, the intermediate layer is formed of an insulator, and spin-polarized electrons are injected in a stacking direction to invert a magnetization direction of the memory layer, so that information is recorded in the memory layer. The magnetic material is also provided for the conductor, so that a magnetic field with current flowing in the conductor is enhanced and a leakage magnetic field is applied to the memory layer to cause a deviation of the magnetization direction of the memory layer. Current in the stacking direction flows into the memory element through the conductor, so that spin-polarized electrons are injected.

### CROSS REFERENCES TO RELATED APPLICATIONS

The present application claims priority to Japanese Patent Application JP2006-143100 filed in the Japanese Patent Office on May 23, 2006, the entire contents of which is being incorporated herein by reference.

### BACKGROUND

The present disclosure relates to a memory including a memory element formed of a memory layer that stores a magnetization state of a ferromagnetic layer as information and a magnetization pinned layer having a pinned magnetization direction, in which current is caused to flow in a direction perpendicular to a film surface to inject spin-polarized electrons, so that a magnetization direction of the memory layer is changed, and also relates to a memory including the memory element that may suitably be used as a non-volatile memory.

High-speed and high-density DRAMs have been widely used as random access memories in information apparatus such as computers.

However, since DRAMs are volatile memories in which information is erased when a power supply is switched off, non-volatile memories in which information is not erased have been desired with the power supply being switched off.

According to Nikkei Electronics, Feb. 12, 2001 (pp. 164-171), for example, magnetic random access memories (MRAMs) that are configured to record information by magnetization of a magnetic material have been attracted attention and developed as potential non-volatile memories.

In an MRAM, current is caused to flow into two types of address wirings almost perpendicular to each other (word lines and bit lines), respectively, to invert magnetization of a magnetic layer of a magnetic memory element in an intersection of the address wirings based on a current magnetic field generated from each address wiring, so that information is recorded.

A schematic view (perspective view) of a typical MRAM is shown in FIG. 1.

In an area isolated by an element isolation layer 102 of a semiconductor substrate 110 such as a silicon substrate, a drain region 108, source regions 107, and gate electrodes 101 are respectively formed which form selective transistors for selecting each memory cell.

Word lines 105 extending in a longitudinal direction in the figure are provided above the gate electrodes 101.

The drain region 108 is formed both on the left and right selective transistors in the figure, and a wiring 109 is connected to the drain region 108.

Magnetic memory elements 103 each having a memory layer in which a magnetization direction is inverted are placed between the word lines 105 and bit lines 106 that are placed above the word lines 105 and extend in a transverse direction in the figure. The magnetic memory elements 103 are formed of magnetic tunnel junction elements (MTJ elements), for example.

Further, the magnetic memory elements 103 are electrically connected to the source regions 107 through a bypass line 111 in a horizontal direction and a contact layer 104 in a vertical direction.

Current is caused to flow into the word lines 105 and the bit lines 106, respectively, to apply a current magnetic field to the magnetic memory elements 103, so that a magnetization direction of the memory layers of the magnetic memory elements 103 can be inverted to record information.

In order to allow a magnetic memory such as MRAM to stably retain recorded information, a magnetic layer (memory layer) to record information preferably has a certain coercive force.

On the other hand, in order to rewrite the recorded information, a certain amount of current is preferably caused to flow into address wirings.

As an element forming an MRAM is reduced in size, a value of current that inverts a magnetization direction tends to be increased. In contrast, since address wirings are thin, it is difficult to cause a sufficient amount of current to flow.

According to Japanese Patent Application Publication No. 2003-17782, U.S. Pat. No. 6,256,223, Phys. Rev. B 54.9353 (1996), and J. Magn. Mat. 159.L1 (1996), for example, under these circumstances, memories configured to use magnetization inversion by spin injection have been attracted attention as those configured to allow magnetization to be inverted using a smaller amount of current.

In magnetization inversion by spin injection, electrons spin-polarized by passing through a magnetic material are injected into another magnetic material to invert magnetization in the other magnetic material.

For example, current is caused to flow into giant magnetoresistance elements (GMR elements) or magnetic tunnel junction elements (MTJ elements) in a direction perpendicular to a film surface of the elements, so that a magnetization direction of at least some of magnetic layers of the elements can be inverted.

Magnetization inversion by spin injection is advantageous in that magnetization can be inverted without increasing an amount of current even if an element is reduced in size.

FIGS. 2 and 3 show schematic views of a memory configured to utilize the above-described magnetization inversion by spin injection. FIG. 2 is a perspective view, and FIG. 3 is a sectional view.

In an area isolated by an element isolation layer 52 of a semiconductor substrate 60 such as a silicon substrate, a drain region 58, source regions 57, and gate electrodes 51 that form selective transistors for selecting each memory cell are respectively formed. Of these, the gate electrodes 51 also function as word lines extending in a longitudinal direction in FIG. 2.

The drain region 58 is formed both on the left and right selective transistors in FIG. 2, and a wiring 59 is connected to the drain region 58.

Memory elements 53 each having a memory layer in which a magnetization direction is inverted by spin injection are placed between the source regions 57 and bit lines 56 that are placed above the source regions 57 and extend in a transverse direction in FIG. 2.

The memory elements 53 are formed of magnetic tunnel junction elements (MTJ elements), for example. Reference numerals 61 and 62 in the figure denote magnetic layers. One of the two magnetic layers 61 and 62 is a magnetization pinned layer in which a magnetization direction is pinned, and the other is a magnetization free layer in which a magnetization direction is changed, specifically, a memory layer.

The memory elements 53 are connected to the bit lines 56 and the source regions 57 respectively through upper or lower contact layers 54. Thus, a magnetization direction of the memory layer can be inverted by spin injection by causing current to flow into the memory elements 53.

Such a memory configured to utilize magnetization inversion by spin injection has a feature in that the memory can have a device structure more simplified as compared with a typical MRAM shown in FIG. 1, and therefore can be a high-density memory.

The memory configured to utilize magnetization inversion by spin injection is more advantageous than a typical MRAM in which magnetization is inverted by an external magnetic field, because an amount of writing current is not increased even if the elements are further reduced in size.

In an MRAM, writing wirings (word lines and bit lines) are provided separate from memory elements, and information is written (recorded) based on a current magnetic field generated by causing current to flow into the writing wirings. Thus, an amount of current for writing can be sufficiently caused to flow into the writing wirings.

In contrast, in a memory configured to utilize magnetization inversion by spin injection, spin injection is preferably performed by causing current to flow into a memory element to invert a magnetization direction of a memory layer.

Since information is written (recorded) by directly causing current to flow into the memory element in this manner, the memory element is connected to a selective transistor to form a memory cell in order to select a memory cell in which writing is performed. In this case, an amount of current caused to flow into the memory element is limited to an amount of current which can be caused to flow into the selective transistor (saturation current of the selective transistor).

Therefore, writing is preferably performed using current in an amount equal to or smaller than the saturation current of the selective transistor, and an amount of current caused to flow into the memory element is preferably reduced by improving spin injection efficiency.

In order to amplify a read signal, a high magnetoresistance change rate may preferably be obtained. To secure a high magnetoresistance change rate, it is effective to provide a memory element having an intermediate layer in contact with both sides of the memory layer that is a tunnel insulating layer (tunnel barrier layer).

When the tunnel insulating layer is used as an intermediate layer in this manner, an amount of current caused to flow into the memory element is limited in order to prevent dielectric breakdown of the tunnel insulating layer. From this viewpoint, an amount of current during spin injection is preferably suppressed.

Typically, a memory is configured to store and retain information written by current, and thus a memory layer that has stability against thermal fluctuation (thermal stability) may be required.

A memory element utilizing magnetization inversion by spin injection has a memory layer having a smaller volume than that of a memory layer of an MRAM of the related art. That is, the memory element tends to have decreased thermal stability.

When the memory layer includes no secured thermal stability, an inverted magnetization direction is inverted again by heat, thereby causing a writing error.

Therefore, thermal stability is a highly important property in the memory element utilizing magnetization inversion by spin injection.

When compared memory elements utilizing magnetization inversion by spin injection that are configured to have equal spin injection efficiency, thermal stability increases with an increase in an amount of saturation magnetization and a volume of a memory layer, thereby consuming a larger amount of current for writing.

A thermal stability index may generally be represented by a thermal stability parameter (Δ).

The thermal stability parameter (Δ) is obtained from the following equation:

Δ=KV/kT

K: anisotropic energy, V: volume of the memory layer, k: Boltzmann constant, T: temperature)

Accordingly, in order for a memory element having a memory layer in which a magnetization direction is inverted by spin injection to be used as a memory, an amount of current necessary for magnetization inversion may be reduced to equal to or smaller than saturation current of a transistor by increasing spin injection efficiency, and thermal stability may be acquired to stably retain written information.

A memory layer generally has an axis of easy magnetization parallel with a magnetization direction of a magnetization pinned layer.

In a stable state, magnetization of a memory layer is parallel or antiparallel with magnetization of a magnetization pinned layer.

However, in magnetization inversion by spin injection, magnetization of a memory element and magnetization of a magnetization pinned layer preferably form a certain finite angle. When both magnetizations form an angle of 0° (parallel state) or 180° (antiparallel state), torque by spin injection remains still and no magnetization inversion is observed.

Magnetization of a memory layer fluctuates around an axis of easy magnetization of the memory layer and slightly deviates from magnetization of a magnetization pinned layer, because of an influence of thermal fluctuation. When spin injection is performed in this state, torque is generated due to a small magnetization deviation, then the deviation is gradually increased, and finally magnetization inversion occurs.

As described above, magnetization inversion is greatly affected by a magnetization direction of a memory layer when spin injection starts. For example, when a magnetization direction of a memory layer is almost parallel or antiparallel with a magnetization direction of a magnetization pinned layer, a long time may be consumed to invert the magnetization direction of the memory layer, and a spin injection memory may no longer be advantageous because information cannot be recorded at high rates.

In addition, a thermal stability parameter Δ may be increased in order to reduce an influence of thermal fluctuation. However, this may force a magnetization direction of a memory layer to agree with a magnetization direction of a magnetization pinned layer directly, and thus it is difficult to meet a demand to reduce an inversion time.

### SUMMARY

According to an embodiment, there is provided a memory that can stably record information at high rates.

A memory according to an embodiment includes at least a memory element having a memory layer that retains information based on a magnetization state of a magnetic material, and a conductor electrically connected to the memory element. The memory element includes a magnetization pinned layer that is provided for the memory layer through an intermediate layer, the intermediate layer that is formed of an insulator, and spin-polarized electrons that are injected in a stacking direction to invert a magnetization direction of the memory layer, so that information is recorded in the memory layer. The magnetic material is provided for at least part of the conductor, so that a magnetic field caused with current flowing in the conductor is enhanced and a leakage magnetic field is applied to the memory layer of the memory element to cause a deviation of the magnetization direction of the memory layer. Current in the stacking direction flows into the memory element through the conductor, so that spin-polarized electrons are injected.

A memory according to the above-described embodiment is configured to include a memory element having a memory layer that retains information based on a magnetization state of a magnetic material, in which a magnetization pinned layer is provided for the memory layer through an intermediate layer, the intermediate layer is formed of an insulator, and spin-polarized electrons are injected in a stacking direction to change a magnetization direction of the memory layer, so that information is recorded in the memory layer. Thus, spin-polarized electrons can be injected by causing current to flow in a stacking direction to record information.

Current in the stacking direction flows into the memory element through the conductor electrically connected to the memory element, so that spin-polarized electrons are injected. Thus, spin-polarized electrons are injected by causing current in the stacking direction to flow into the memory element through the conductor, so that information can be recorded in the memory element by spin injection.

Further, the magnetic material is provided for at least part of the conductor, so that a magnetic field caused with current flowing in the conductor is enhanced and a leakage magnetic field is applied to the memory layer of the memory element to cause a deviation of a magnetization direction of the memory layer. Accordingly, a magnetization direction of the memory layer is caused to deviate (from a direction of axis of easy magnetization of the memory layer) by a leakage magnetic field from the magnetic material, so that an amount of time used for inverting a magnetization direction of the memory layer to record information may be reduced. Use of a memory of the above-described embodiment of the present invention may reduce an amount of time for inverting a magnetization direction of the memory layer to record information, and thus can record information at high rates.

Further, an amount of current for inverting magnetization can be reduced by causing magnetization of the memory layer to deviate, and hence power consumption for the memory can be decreased.

In addition, information can be recorded at high rates while securing sufficient thermal stability.

Accordingly, a memory capable of recording information at high rates with high reliability can be achieved.

Additional features and advantages are described herein, and will be apparent from, the following Detailed Description and the figures.

### BRIEF DESCRIPTION OF THE FIGURES

FIG. 1 is a perspective view schematically showing a configuration of an MRAM of the related art.

FIG. 2 is a schematic configuration diagram (perspective view) of a memory utilizing magnetization inversion by spin injection.

FIG. 3 is a sectional view of the memory of FIG. 2.

FIG. 4 is a schematic configuration diagram (perspective view) of a memory according to an embodiment.

FIG. 5 is a sectional view of a memory element of FIG. 4.

FIG. 6 is an enlarged perspective view of a main part (a vicinity of memory element) of a memory having a configuration of the related art which utilizes magnetization inversion by spin injection.

FIG. 7 is an enlarged perspective view of a main part (a vicinity of memory element) of the memory of FIG. 4.

FIGS. 8A and 8B are views describing an effect of a magnetic field when current is caused to flow into the configuration of FIG. 7.

FIG. 9 is an enlarged perspective view of a main part (a vicinity of memory element) of a memory according to another embodiment.

FIGS. 10A and 10B are views describing an effect of a magnetic field when current is caused to flow into the configuration of FIG. 9.

FIG. 11 is an enlarged perspective view of a main part (a vicinity of memory element) of a memory according to still another embodiment.

FIGS. 12A and 12B are views describing an effect of a magnetic field when current is caused to flow into the configuration of FIG. 11.

### DETAILED DESCRIPTION

An outline is illustrated below before describing the specific embodiments.

In an embodiment, information is recorded by inverting a magnetization direction of a memory layer of a memory element by the above-described spin injection. The memory layer is formed of a magnetic material such as a ferromagnetic layer and retains information based on a magnetization state (magnetization direction) of the magnetic material.

In a basic operation of inverting a magnetization direction of a magnetic layer by spin injection, current having a certain threshold value (Ic) or higher is caused to flow into a memory element formed of a giant magnetoresistance element (GMR element) or magnetic tunnel junction element (MTJ element) in a direction perpendicular to a film surface of the memory element. Here, a polarity (direction) of current depends on a magnetization direction to be inverted.

Magnetization inversion does not occur when current having an absolute value smaller than the threshold value is caused to flow or current is caused to flow in a short time.

A threshold value Jc of current for inverting a magnetization direction of a magnetic layer by spin injection is phenomenologically represented by the following equation 1 (see R. H. Koch et al., Phys. Rev. Lett. 92 0883021 (2004), for example).

$${J}_{c} = {J}_{c 0} ( 1 + \frac{{τ}_{1}}{t} ln [ \frac{π}{2 θ} ] ) \qquad 1$$

In the equation 1, J_{c0} is a property value determined by magnetic properties of a memory layer and provides a lower limit of an amount of inversion current, τ₁ is time determined by an amount of saturation magnetization and a damping constant of the memory layer and is a value roughly in the order of nanoseconds, t is a writing time, and θ is an angle formed by magnetization of the memory layer and magnetization of a magnetization pinned layer.

As clear from the equation, an amount of inversion current Jc is rapidly increased when θ is zero (when magnetization of a memory layer is parallel or antiparallel with magnetization of a magnetization pinned layer). θ may not be necessarily a constant value, and randomly moves around an axis of easy magnetization by influence of thermal fluctuation.

When the θ is a value approximate to zero at the start of spin injection, an amount of current caused to flow may not complete magnetization inversion of a memory layer and a writing failure error occurs due to consuming a long time for the inversion.

In an embodiment, a memory is configured to prevent a writing failure error caused when θ is accidentally a value approximate to zero as described above.

When current is caused to flow into a memory element through a metal conductor connected to the memory element, an annular magnetic field is generated around the current.

In typical magnetization inversion by spin injection, a magnetization direction of a memory layer is not significantly changed by the annular current magnetic field.

By contrast, in an embodiment of the present invention, a ring current magnetic field is concentrated on a memory layer to cause magnetization of the memory layer to slightly deviate from an axis of easy magnetization. Thus, an amount of time for inverting magnetization may be reduced.

In an embodiment, a magnetic material is provided for a metal conductor electrically connected to a memory element, so that a ring current magnetic field is enhanced and concentrated on a memory layer to cause magnetization of the memory layer to deviate from an axis of easy magnetization. The metal conductor having the magnetic material provided may be directly connected to the memory element, or may be indirectly connected to the memory element through another conductor; that is, the metal conductor may be electrically connected to the memory element.

The magnetic material is provided to cover part or an entire metal conductor, for example, so that a ring current magnetic field can be enhanced and the current magnetic field can be concentrated on the memory layer.

In a configuration according to an embodiment, an amount of time used for inverting magnetization can be reduced, and thus information can be recorded at high rates.

Further, magnetization of the memory layer is caused to deviate to increase θ in the equation 1, so that an amount of current for inverting the magnetization can be reduced and hence power consumption for the memory may be decreased.

In addition, an amount of time for inverting magnetization of the memory layer can be reduced even if a thermal stability parameter Δ is not reduced. Thus, information can be recorded at high rates while securing sufficient thermal stability.

Accordingly, a memory capable of recording information at high rates can be realized with high reliability.

Further, in an embodiment, a magnetic tunnel junction (MTJ) element is formed using a tunnel insulating layer formed of an insulator as a non-magnetic intermediate layer between a memory layer and a magnetization pinned layer, allowing to accommodate a saturation current value of a selective transistor.

This allows a magnetic tunnel junction (MTJ) element formed using a tunnel insulating layer to increase a magnetoresistance change rate (MR rate) and a read signal strength as compared with a giant magnetoresistance (GMR) element formed using a non-magnetic conductive layer.

Magnesium oxide (MgO) is particularly used as a material for a tunnel insulating layer, so that a magnetoresistance change rate (MR rate) can be increased as compared with a case of using aluminum oxide that has been generally used.

Spin injection efficiency generally depends on an MR rate. As the MR rate increases, the spin injection efficiency is further improved, thereby further reducing a density of magnetization inversion current.

Accordingly, magnesium oxide is used as a material for a tunnel insulating layer as an intermediate layer and a memory layer having the above-described configuration is used, so that an amount of writing threshold current by spin injection can be reduced, and hence information can be written (recorded) using a small amount of current. In addition, writing signal strength can be increased.

Thus, an MR rate (TMR rate) is secured, so that an amount of writing threshold current by spin injection can be reduced, and hence information can be written (recorded) using a small amount of current.

In addition, writing signal strength can be increased.

When a tunnel insulating layer is formed of a magnesium oxide (MgO) film, the MgO film may be preferably crystallized and may maintain crystalline orientation in a 001 direction.

In an embodiment, an intermediate layer between a memory layer and a magnetization pinned layer may not have to be formed of magnesium oxide (tunnel insulating layer); however, may be formed with various insulators, dielectrics, or semiconductors such as aluminum oxide, aluminum nitride, SiO₂, Bi₂O₃, MgF₂, CaF, SrTiO₂, AlLaO₃, and Al—N—O.

Further, in order to achieve excellent magnetoresistance properties (MR properties) when using magnesium oxide for an intermediate layer, an annealing temperature is preferably at 300° C. or more, and preferably 340° C. to 360° C. Such an annealing temperature is higher than an annealing temperature (250° C. to 280° C.) in the case of aluminum oxide that has been used for an intermediate layer in the related art.

Such an annealing temperature may be necessary for forming an appropriate internal structure or crystalline structure of a tunnel insulating layer of magnesium oxide or the like.

Consequently, improved MR properties can be achieved using a heat-resistant ferromagnetic material that is resistant to annealing at such a high temperature for a ferromagnetic layer of a memory element.

Other configurations of a memory element may be the same as previously known configurations of a memory element in which information is recorded by spin injection.

Next, specific embodiments are described.

FIG. 4 shows a schematic configuration diagram (perspective view) of a memory according to an embodiment.

The memory has a memory element placed near an intersection of two types of address wires (word lines and bit lines, for example) perpendicular to each other.

Specifically, in an area isolated by an element isolation layer 2 of a semiconductor substrate 10 such as a silicon substrate, a drain region 8, source regions 7, and gate electrodes 1 forming selective transistors for selecting each memory cell are respectively formed. Of these, the gate electrodes 1 also function as one type of address wirings (word lines, for example) extending in a longitudinal direction in the figure.

The drain region 8 is formed both on the left and right selective transistors in the figure, and a wiring 9 is connected to the drain region 8.

Memory elements 3 are placed between the source regions 7 and the other type of address wirings (bit lines, for example) 6 that are placed above the source regions 7 and extend in a transverse direction in the figure. The memory elements 3 each have a memory layer formed of a ferromagnetic layer in which a magnetization direction is inverted by spin injection.

The memory elements 3 are placed near an intersection of the two types of address wirings 1 and 6.

The memory elements 3 are connected to the bit lines 6 and the source regions 7 respectively through upper or lower contact sections 4 and 5.

Thus, a magnetization direction of the memory layer can be inverted by spin injection by causing current to flow into the memory elements 3 in a vertical direction through the two types of address wirings 1 and 6.

FIG. 5 shows a sectional view of the memory element 3 of the memory according to the present embodiment.

As shown in FIG. 5, the memory element 3 has a magnetization pinned layer 31 provided under a memory layer 17 in which a direction of magnetization M1 is inverted by spin injection. An antiferromagnetic layer 12 is provided under the magnetization pinned layer 31, and a magnetization direction of the magnetization pinned layer 31 is pinned by the antiferromagnetic layer 12.

An insulating layer 16 is provided as a tunnel barrier layer (tunnel insulating layer) between the memory layer 17 and the magnetization pinned layer 31, and an MTJ element is formed of the memory layer 17 and the magnetization pinned layer 31.

A ground layer 11 is formed under the antiferromagnetic layer 12, and a cap layer 18 is formed on the memory layer 17.

The magnetization pinned layer 31 has a stacked ferrimagnetic structure.

Specifically, the magnetization pinned layer 31 includes two ferromagnetic layers 13 and 15 that are stacked and antiferromagnetically bonded through a non-magnetic layer 14.

Since the ferromagnetic layers 13 and 15 of the magnetization pinned layer 31 form a stacked ferromagnetic structure, magnetization M13 of the ferromagnetic layer 13 is right-directed and magnetization M15 of the ferromagnetic layer 15 is left-directed; that is, the magnetizations are oppositely directed. Thus, magnetic fluxes leaked from the ferromagnetic layers 13 and 15 of the magnetization pinned layer 31 cancel each other.

A material for the ferromagnetic layers 13 and 15 of the magnetization pinned layer 31 is not specifically limited. An alloy material formed of one or more of iron, nickel, and cobalt may be used as such a material. The material may further contain a transition metal element such as Nb, Zr, Gd, Ta, Ti, Mo, Mn, or Cu, or a light element such as Si, B, or C. Further, the ferromagnetic layers 13 and 15 may be formed by directly stacking a plurality of films with materials differing from each other (not through a non-magnetic layer), for example, by forming stacked films of CoFe/NiFe/CoFe.

As a material for the non-magnetic layer 14 forming a stacked ferrimagnetic structure of the magnetization pinned layer 31, ruthenium, copper, chromium, gold, silver, or the like may be used.

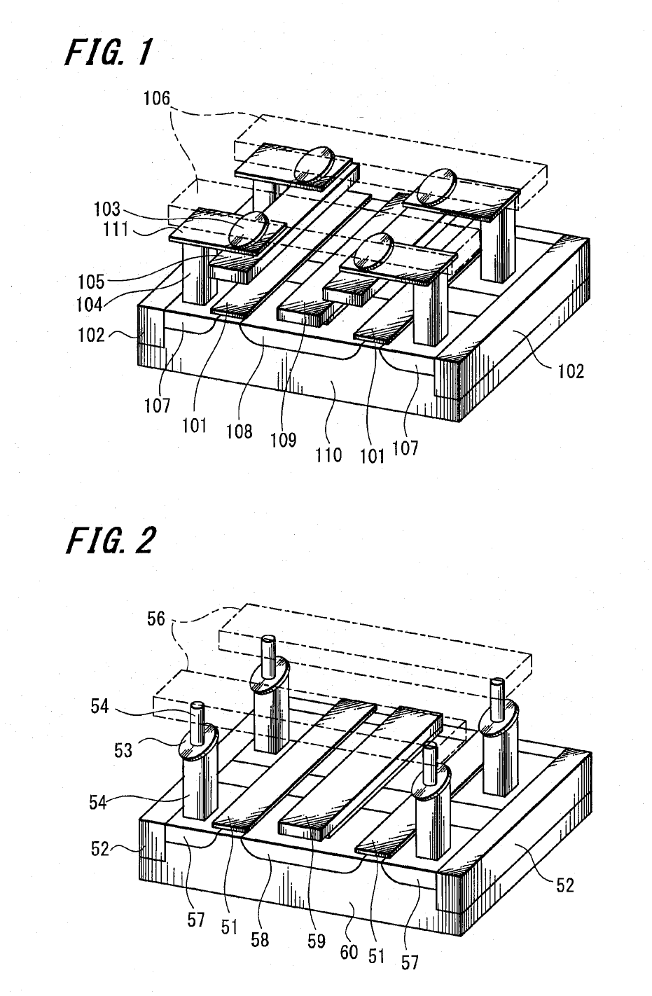

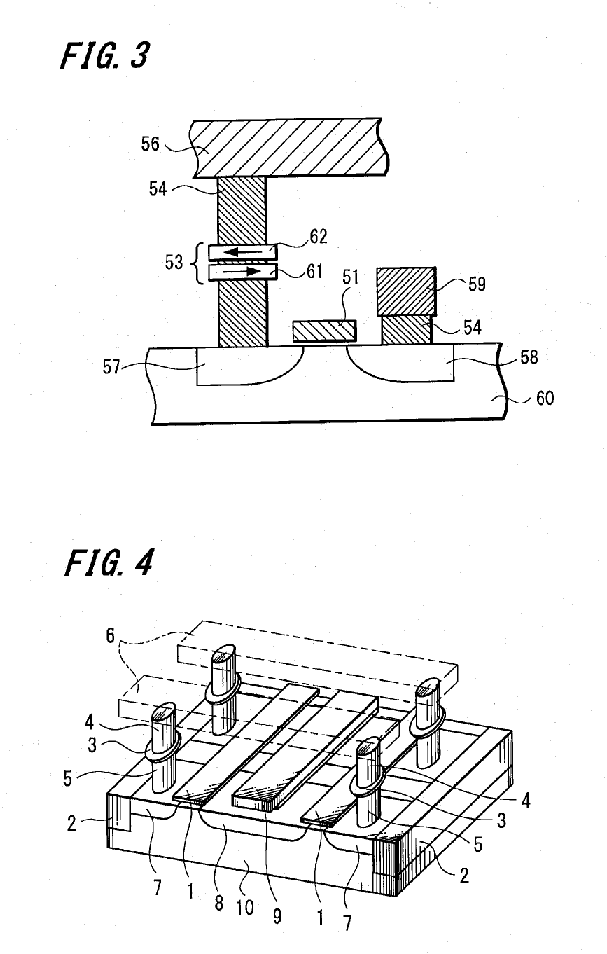

The memory according to the present embodiment differs from a memory of the related art utilizing spin injection as shown in FIGS. 2 and 3, particularly in terms of the contact sections 4 and 5 connected to the memory element 3.

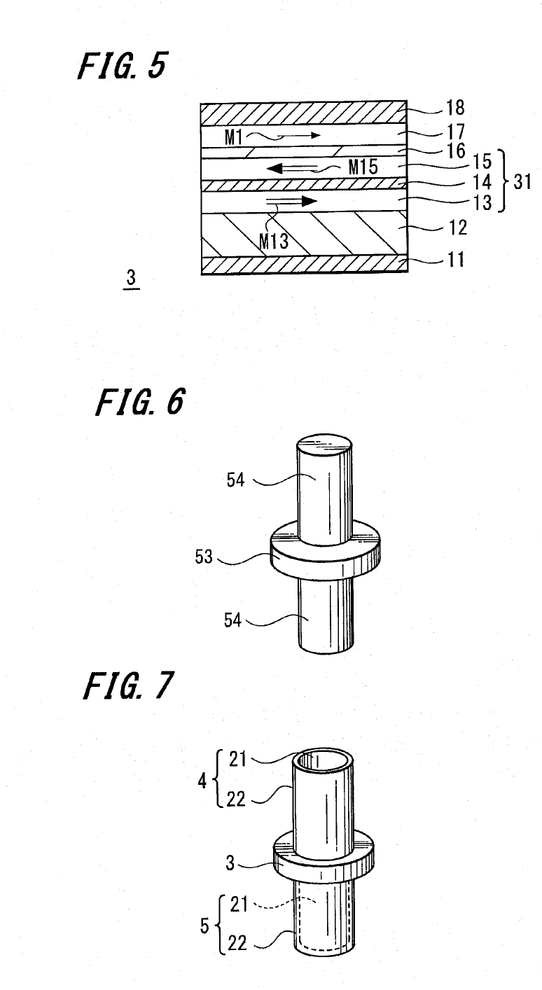

FIG. 6 shows an enlarged perspective view of the vicinity of a memory element 53 forming a memory of the related art utilizing spin injection as a comparative example as shown in FIGS. 2 and 3 according to an embodiment. As shown in FIG. 6, contact sections 54 are connected to upper and lower surfaces of the memory element 53, respectively, and the contact sections 42 are formed of metal conductors.

In a configuration of FIG. 6, writing voltage is applied to the contact sections 54 on and under the memory element 53, which are selected by a selective transistor or the like, so that the writing current is caused to flow into the memory element 53 and a magnetization direction is inverted by spin injection.

Here, an amount of time for inverting magnetization relates to a magnetization direction of a memory layer of the memory element 53, as described above. Exceedingly long time may be used for writing when the magnetization direction of the memory layer accidentally corresponds to a magnetization direction of a magnetization pinned layer (angle: 0° or 180°).

FIG. 7 shows a perspective view of a main part of a memory cell of the memory shown in FIG. 4 (enlarged perspective view of the memory element 3 and its vicinity) for comparison.

In the present embodiment, as shown in FIG. 7, the upper and lower contact sections 4 and 5 connected to the memory element 3 are respectively formed by covering a metal conductor 21 with a magnetic material 22.

As a material for the magnetic material 22, any magnetic material having a high permeability may exhibit the same effect.

For example, a general ferromagnetic alloy containing Co, Fe, or Ni as a main component may be used. Specifically, a CoFe alloy, an NiFe alloy, or a CoNiFe alloy may be used. Such a ferromagnetic alloy may also contain one or more additional elements including light elements such as B, C, and N; transition metal elements such as Ti, V, Cr, Zr, Nb, Mo, Hf, Ta, and W; rare earth elements such as Gd; or noble metal elements such as Pt and Pd. The ferromagnetic alloy may preferably contain such an additional element.

There are no specific limitations to a method of forming a structure of the contact section 4 or 5 of the present embodiment. For example, the contact section can be formed as follows.

First, a through-hole to form the contact section is formed in a surface-covered insulating layer. For example, in the case of the memory of FIG. 4, a through-hole is formed to reach the source region 7 and the memory element 3.

Second, a thin film of the magnetic material 22 is formed along an inner wall of the through-hole.

Third, the magnetic material 22 formed on a bottom of the through-hole is removed.

Fourth, the metal conductor 21 is formed by filling the through-hole with it, and then the metal conductor 21 remaining on the insulating layer is removed.

The contact section 4 or 5 having a structure in which the metal conductor 21 is covered with the magnetic material 22 can be formed in this manner.

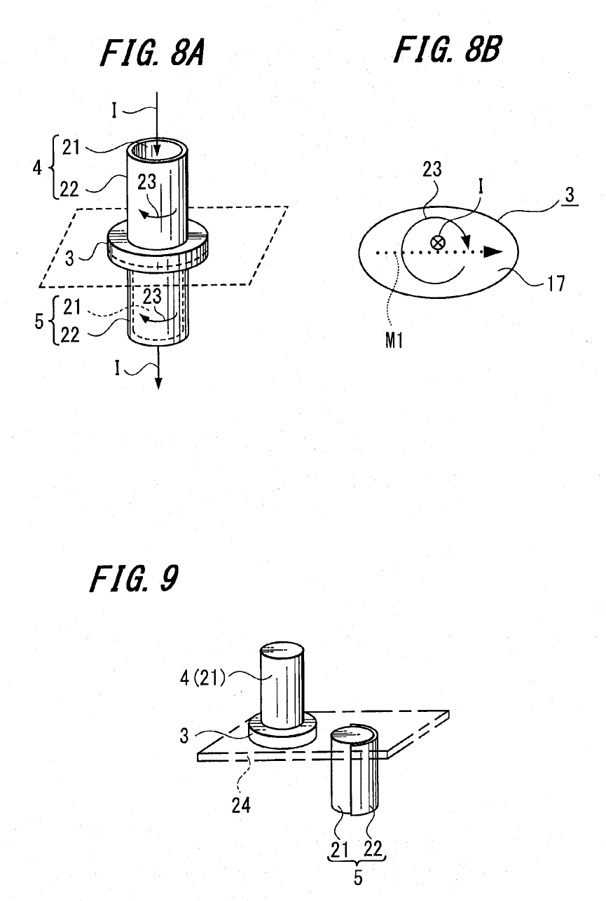

According to the present embodiment, current I is caused to flow into the memory element 3 through the metal conductors 21 from up to down as shown in FIG. 8A in order to perform spin injection.

In this case, a clockwise current magnetic field 23 is generated in the magnetic materials 22 of the upper and lower contact sections 4 and 5 by the downward current I.

A clockwise current magnetic field 23 is then generated in the memory layer 17 of the memory element 3 as shown in FIG. 8B in a horizontal plane across the memory layer of the memory element 3 indicated by the dotted line in FIG. 8A, by a leakage magnetic field from the magnetic materials 22 of the upper and lower contact sections 4 and 5 and the current magnetic field by the downward current I.

The current magnetic field 23 can shift a direction of magnetization M1 of the memory layer 17 to deviate from a direction of axis of easy magnetization (a direction of magnetization M13 or M15 of a magnetization pinned layer 31) to a direction of axis of hard magnetization.

The magnetic materials 22 having a high permeability are provided for the contact sections 4 and 5 in this manner, so that the current magnetic field 23 by the current I flowing in the metal conductors 21 is concentrated around the magnetic materials 22. As a result, the strong magnetic field 23 is generated around the memory layer 17, and consequently a direction of magnetization M1 of the memory layer 17 is caused to slightly deviate from a direction of magnetization M13 or M15 of the magnetization pinned layer 31.

Here, inversion of magnetization M1 of the memory layer 17 is caused only by spin injection, and the concentrated current magnetic field 23 is used for initiating spin injection.

When current is caused to flow upward and inverse to the current I in FIG. 8A, a counter-clockwise magnetic field is generated in the memory layer 17 by the magnetic materials 22 of the contact sections 4 and 5, and the magnetic field makes a direction of magnetization M1 of the memory layer 17 slightly deviate from a direction of magnetization M13 or M15 of the magnetization pinned layer 31.

Accordingly, when a direction of magnetization M1 of the memory layer 17 is inverted to any directions, the direction of magnetization M1 of the memory layer 17 can be caused to deviate with an effect of the magnetic field.

In the above-described present embodiment, the metal conductors 21 into which current is caused to flow are covered with the magnetic materials 22 in the contact sections 4 and 5 on and under the memory element 3. Thus, the current magnetic field 23 with current flowing in the metal conductors 21 can be concentrated on the magnetic materials 22.

The current magnetic field 23 concentrated on the magnetic materials 22 can be applied to the memory element 3 from the magnetic materials 22 as a leakage magnetic field 23. Thus, a direction of magnetization M1 of the memory layer 17 of the memory element 3 can be caused to deviate from a direction of magnetization M13 or M15 of the magnetization pinned layer 31, specifically, a direction of axis of easy magnetization to make it easy to invert the direction of magnetization M1 of the memory layer 17.

Consequently, an amount of time for inverting a direction of magnetization M1 of the memory layer 17 can be reduced, and thus information can be recorded at high rates.

Further, in the present embodiment, magnetization M1 of the memory layer 17 is caused to deviate to increase θ in the equation 1, so that an amount of current for inverting the magnetization M1 can be reduced and hence power consumption for the memory may be decreased.

In addition, an amount of time for inverting magnetization M1 of the memory layer 17 can be reduced even if a thermal stability parameter Δ is not decreased. Thus, information can be recorded at high rates while securing sufficient thermal stability.

Accordingly, a memory capable of recording information at high rates can be realized with high reliability.

In FIG. 7, the metal conductors 21 are covered with the magnetic materials 22 in the upper and lower contact sections 4 and 5. However, the magnetic material 22 may also be provided for only one of the contact sections.

In the above-described embodiment shown in FIGS. 4, 5, 7, and 8, the metal conductors 21 of the upper and lower contact sections 4 and 5 are on a single straight line. However, metal conductors of upper and lower contact sections may be shifted through another metal layer such as a bypass line 111 of an MRAM shown in FIG. 1. An example of this case is described below.

FIG. 9 shows an enlarged perspective view of a main part (a vicinity of memory element) of a memory according to another embodiment.

In the present embodiment, in particular, a memory element 3 is connected to a metal conductor 21 of a lower contact section 5 through a bypass line 24 indicated by a dot-dash-line in the figure, and the metal conductors 21 of the upper and lower contact sections 4 and 5 are shifted in a transverse direction.

The upper contact section 4 has only the metal conductor 21 and does not have a magnetic material 22. The lower contact section 5 has the metal conductor 21, right half of which is covered with the magnetic material 22.

There are no specific limitations to a method of forming a structure of the lower contact section 5 of the present embodiment. For example, the contact section 5 can be formed by partially modifying the formation method described for the previous embodiment.

For example, the magnetic material 22 may be formed on right half of a through-hole of an insulating layer by depositing the magnetic material 22 obliquely or masking left half of the through-hole. The magnetic material 22 may also be formed on an entire inner wall of a through-hole and then remove the magnetic material 22 formed on left half of the through-hole.

Alternatively, the columnar metal conductor 21 may be formed and then the magnetic material 22 may be deposited from the upper right to form the magnetic material 22 on right half of the metal conductor 21.

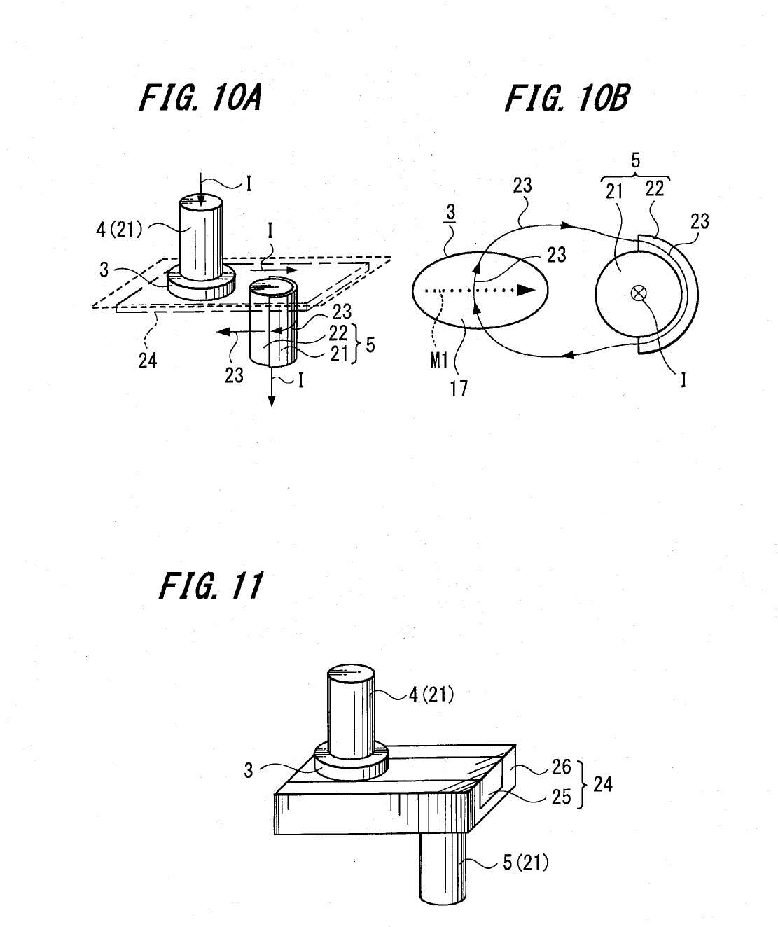

According to the present embodiment, current I is caused to flow into the memory element 3 through the metal conductors 21 from up to down as shown in FIG. 10A in order to perform spin injection.

In this case, a clockwise current magnetic field 23 is generated in the magnetic material 22 of the lower contact section 5 by the downward current I. Since the magnetic material 22 of the lower contact section 5 is provided only for right half of the metal conductor 21, the current magnetic field 23 is leaked from the contact section 5 to the left.

Then, a magnetic field 23 directed from front to back is generated in a memory layer 17 of the memory element 3 as shown in FIG. 10B in a horizontal plane across the memory layer of the memory element 3 which is indicated by the dotted line in FIG. 10A, by the leakage magnetic field from the magnetic material 22 of the lower contact section 5.

The magnetic field 23 can shift a direction of magnetization M1 of the memory layer 17 to deviate from a direction of axis of easy magnetization (a direction of magnetization M13 or M15 of a magnetization pinned layer 31) to a direction of axis of hard magnetization.

When current is caused to flow upward and inverse to the current I in FIG. 8A, a counter-clockwise magnetic field is generated in the memory layer 17 by the magnetic material 22 of the lower contact section 5, and the magnetic field shifts a direction of magnetization M1 of the memory layer 17 to slightly deviate from a direction of magnetization M13 or M15 of the magnetization pinned layer 31.

Accordingly, when a direction of magnetization M1 of the memory layer 17 is inverted to any directions, the direction of magnetization M1 of the memory layer 17 can be caused to deviate with an effect of the magnetic field.

In the above-described present embodiment, the metal conductor 21 into which current is caused to flow is covered with the magnetic material 22 in the contact section 5 under the memory element 3. Thus, the current magnetic field 23 with current flowing in the metal conductor 21 can be concentrated on the magnetic material 22.

The current magnetic field 23 concentrated on the magnetic material 22 can be applied to the memory element 3 from the magnetic material 22 as a leakage magnetic field 23. Thus, a direction of magnetization M1 of the memory layer 17 of the memory element 3 can be caused to deviate from a direction of magnetization M13 or M15 of the magnetization pinned layer 31, specifically, a direction of axis of easy magnetization to facilitate to invert the direction of magnetization M1 of the memory layer 17.

Further, since the metal conductor 21 of the contact section 5 under the memory element 3 is placed to the right of the memory element 3, the magnetic field 23 can be more effectively applied to the memory layer 17 by covering only a right half side of the metal conductor 21, the opposite side to the memory element 3, with the magnetic material 22.

Since a direction of magnetization M1 of the memory layer 17 can be easily inverted, an amount of time for inverting the direction of magnetization M1 of the memory layer 17 may be reduced. Thus, information can be recorded at high rates.

In the present embodiment, an amount of current for inverting magnetization M1 of the memory layer 17 can be reduced and hence power consumption for the memory may be decreased. Accordingly, information can be recorded at high rates while securing sufficient thermal stability, as in the previous embodiment.

Thus, a memory capable of recording information at high rates can be realized with high reliability.

The upper contact section 4 and the memory element 3 may be shifted and connect the upper contact section 4 to the memory element 3 through a bypass line 24. In this case, the magnetic material is provided for the upper contact section 4.

The contact section may be shifted with the memory element in any directions. In any such case, the magnetic material may be provided for a side of the metal conductor opposite to the memory element.

FIG. 11 shows an enlarged perspective view of a main part (a vicinity of memory element) of a memory according to still another embodiment of the present invention.

In the present embodiment, a magnetic field is concentrated on a bypass line.

A memory element 3 is connected to a metal conductor 21 of a lower contact section 5 through a bypass line 24, and the metal conductors 21 of the upper and lower contact sections 4 and 5 are shifted in a transverse direction.

In the bypass line 24, three surfaces (lower surface and both side surfaces) other than an upper surface in contact with the memory element 3 of a metal layer (metal conductor) 25 are covered with a magnetic material 26.

The upper and lower contact sections 4 and 5 have only the metal conductors 21 and include no magnetic material.

In such a configuration, a magnetic field generated when current flows in the bypass line 24 is concentrated around a memory layer 17, which facilitates a deviation of a direction of magnetization M1 of the memory layer 17 from a direction of magnetization M13 or M15 of a magnetization pinned layer 31.

There are no specific limitations to a method of forming a structure of the bypass line 24 of the present embodiment. For example, the bypass line can be formed as follows.

### First, a layer of the magnetic material 26 is formed.

Second, a groove-like concave portion in which the metal conductor 25 is to be embedded is formed in the layer of the magnetic material 26.

Third, the metal conductor 25 is formed by embedding the metal conductor 25 in the groove-like concave portion.

Fourth, the magnetic material 26 in which the metal conductor 25 is embedded is patterned into the bypass line 24.

The bypass line 24 having a structure in which the metal conductor 25 is covered with the magnetic material 26 can be formed in this manner.

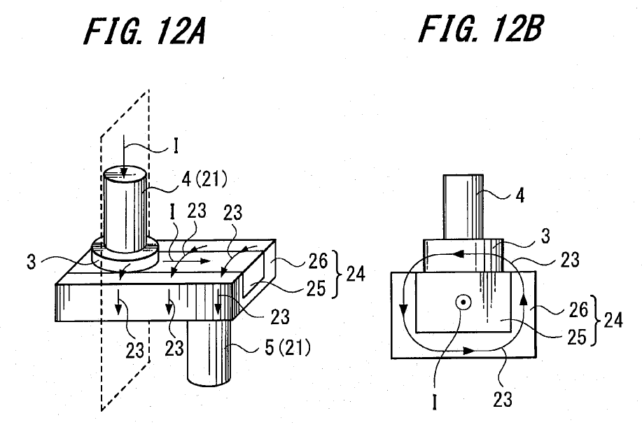

According to the present embodiment, current I is caused to flow into the memory element 3 through the metal conductors 21 from up to down as shown in FIG. 12A in order to perform spin injection.

In this case, the current I flows down in the contact sections 4 and 5; whereas the current I flows to the right in the metal layer 25 of the bypass line 24. A current magnetic field 23 is generated in the magnetic material 26 covering the metal layer 25 by the rightward current I. Since the magnetic material 26 covers only three surfaces (lower surface and both side surfaces) of the metal layer 25, the current magnetic field 23 is leaked from the bypass line 24 in an upper direction.

Then, a magnetic field 23 directed from back to front is generated in the memory element 3 as shown in FIG. 12B in a vertical plane across the memory element 3 indicated by the dotted line in FIG. 12A, by the leakage magnetic field from the magnetic material 25 of the bypass line 24.

The magnetic field 23 can shift a direction of magnetization M1 of the memory layer 17 of the memory element 3 to deviate from a direction of axis of easy magnetization (a direction of magnetization M13 or M15 of a magnetization pinned layer 31) to a direction of axis of hard magnetization.

When current is caused to flow upward and inverse to the current I in FIG. 12A, leftward current is generated in the bypass line 24. The leftward current generates a magnetic field inverse to the magnetic field 23 in FIG. 12A in the magnetic material 26 of the bypass line 24. Since the magnetic field generates a magnetic field directed from front to back in the memory element 3, a direction of magnetization M1 of the memory layer 17 can be caused to deviate from a direction of magnetization M13 or M15 of the magnetization pinned layer 31.

Accordingly, when a direction of magnetization M1 of the memory layer 17 is inverted to any directions, the direction of magnetization M1 of the memory layer 17 can be caused to deviate with an effect of the magnetic field.

In the above-described present embodiment, the metal conductor 25 into which current is caused to flow is covered with the magnetic material 26 in the bypass line 24 placed under and connected to the memory element 3. Thus, the current magnetic field 23 with current flowing in the metal conductor 25 can be concentrated on the magnetic material 26.

The current magnetic field 23 concentrated on the magnetic material 26 can be applied to the memory element 3 from the magnetic material 26 as a leakage magnetic field 23. Thus, a direction of magnetization M1 of the memory layer 17 of the memory element 3 can be caused to deviate from a direction of magnetization M13 or M15 of the magnetization pinned layer 31, specifically, a direction of axis of easy magnetization to facilitate to invert the direction of magnetization M1 of the memory layer 17.

Consequently, an amount of time for inverting a direction of magnetization M1 of the memory layer 17 can be reduced, and thus information can be recorded at high rates.

In the present embodiment, an amount of current for inverting magnetization M1 of the memory layer 17 can be reduced and hence power consumption for the memory may be decreased. Accordingly, information can be recorded at high rates while securing sufficient thermal stability, as in the previous embodiment. Thus, a memory capable of recording information at high rates can be realized with high reliability.

In each of the above-described embodiments, the metal conductors 21 and 25 to supply current to the memory layer 17 are appropriately covered with the magnetic materials 22 and 26, respectively, so that the concentrated magnetic field 23 is applied to the memory layer 17 to shift a direction of magnetization M1 of the memory layer to slightly deviate from a direction of magnetization M13 or M15 of the magnetization pinned layer 31. Consequently, spin injection torque acts greatly on the magnetization M1 of the memory layer 17, and thus the direction of magnetization M1 of the memory layer 17 can be inverted in a short time.

It should be appreciated that an embodiment may employ not only a film configuration of the memory element 3 shown in each of the above-described embodiments but also various other film configurations.

In FIG. 5, the magnetization pinned layer 31 has a stacked ferrimagnetic structure formed of the two ferromagnetic layers 13 and 15 and the non-magnetic layer 14. However, the magnetization pinned layer may be formed of a single ferromagnetic layer, for example.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A memory comprising:
at least a memory element having
a memory layer that retains information based on a magnetization state of a magnetic material, and
a magnetization pinned layer provided for the memory layer through an intermediate layer, the intermediate layer comprising an insulator, and spin-polarized electrons are injected in a stacking direction to invert a magnetization direction of the memory layer, so that information is recorded in the memory layer; and
a conductor electrically connected to the memory element, wherein the magnetic material is provided for at least part of the conductor, so that a magnetic field caused by current flowing in the conductor is enhanced and a leakage magnetic filed is applied to the memory layer of the memory element to cause a deviation of the magnetization direction of the memory layer, and
wherein current in the stacking direction flows into the memory element through the conductor, so that spin-polarized electrons are injected.

2. A memory according to claim 1, wherein
the conductor is placed on each of upper and lower surfaces of the memory element, and
the magnetic material is provided to cover at least one of the upper and lower conductors.
